(19) United States
(12) Patent Application Publication
(10) Pub. No.: US 2022/0245307 A1
(43) Pub. Date: Aug. 4, 2022

(54) HYBRID PHYSICS/MACHINE LEARNING MODELING OF PROCESSES

(71) Applicant: Applied Materials, Inc., Santa Clara, CA (US)

(72) Inventors: Prashanth Kothnur, San Jose, CA (US); Karthik Ramanathan, Bangalore (IN); Ajit Balakrishna, Santa Clara, CA (US); Kartik Shah, Santa Clara, CA (US); Umesh Kelkar, Santa Clara, CA (US); Vishwas Pandey, Bangalore (IN); Prasoon Shukla, Lucknow (IN); Sushil Arun Samant, Dombivli (E) (IN)

(21) Appl. No.: 17/166,965

(22) Filed: Feb. 3, 2021

(51) Int. Cl. G06F 30/27; G05B 13/02; G05B 17/02; H01L 21/67; H03H 17/02

(52) U.S. Cl. CPC G06F 30/27; G05B 13/0265; H03H 2017/0205; H01L 21/67253; H03H 17/0202; G05B 17/02

(57) ABSTRACT

Embodiments described herein include processes for generating a hybrid model for modeling processes in semiconductor processing equipment. In a particular embodiment, method of creating a hybrid machine learning model comprises identifying a first set of cases spanning a first range of process and/or hardware parameters, and running experiments in a lab for the first set of cases. The method may further comprise compiling experimental outputs from the experiments, and running physics based simulations for the first set of cases. In an embodiment, the method may further comprise compiling model outputs from the simulations, and correlating the model outputs with the experimental outputs with a machine learning algorithm to provide the hybrid machine learning model.

### BACKGROUND

### 1) Field

Embodiments of the present disclosure pertain to the field of semiconductor processing and, in particular, to hybrid modelling of processes in a semiconductor processing tool and the use of virtual sensors.

### 2) Description of Related Art

Semiconductor substrate processing has been increasing in complexity as semiconductor devices continue to progress to smaller feature sizes. A given process may include many different process parameters (i.e., knobs) that can be individually controlled in order to provide a desired outcome on the wafer. For example, the desired outcome on the wafer may refer to a feature profile, a thickness of a layer, a chemical composition of a layer, or the like. As the number of knobs increase, the theoretical process space available to tune and optimize the process grows exponentially large.

When hardware changes to the semiconductor processing tool are made, the knobs need to be changed in order to account for the new hardware setup. Due to the cost of implementing hardware changes, there is value in being able to predict or estimate the performance of the new hardware, prior to physically building the hardware. The traditional approach is to get a qualitative understanding from previous experiments for similar hardware, and use intuition and trial-error (both of which may be subjective) in order to estimate the performance of the new hardware and/or identify new processing parameters. In some applications, insight from physics models may also be used. However, the physics based approaches may be incomplete or disparate (e.g., separate models for temperature, plasma, and flow). That is, there is no existing approach that provides a quantitative and objective path to adjust a process for new hardware.

### SUMMARY

Embodiments described herein include processes for generating a hybrid model for modeling processes in semiconductor processing equipment. In a particular embodiment, method of creating a hybrid machine learning model comprises identifying a first set of cases spanning a first range of process and/or hardware parameters, and running experiments in a lab for the first set of cases. The method may further comprise compiling experimental outputs from the experiments, and running physics based simulations for the first set of cases. In an embodiment, the method may further comprise compiling model outputs from the simulations, and correlating the model outputs with the experimental outputs with a machine learning algorithm to provide the hybrid machine learning model.

Additional embodiments may include a semiconductor processing tool with a virtual sensor. In an embodiment, the semiconductor processing tool comprises a chamber, and a controller for changing a control variable of the semiconductor processing tool. In an embodiment, the controller receives, as an input, a difference between a measured output variable from the chamber and an output variable set-point. In an embodiment, the semiconductor processing tool further comprises a virtual sensor for generating an estimated system state variable that is used to determine the output variable set-point.

Additional embodiments may comprise a method of creating a hybrid machine learning model. In an embodiment, the method comprises identifying a first set of cases spanning a first range of process and/or hardware parameters, and running a physics based simulation for the first set of cases. In an embodiment, the method further comprises compiling outputs from the physics based simulation, and using a first machine learning algorithm to generate a reduced order physics simulation model. In an embodiment, the method may further comprise identifying a second set of cases spanning a second range of process and/or hardware parameters, where the second set of cases is smaller than the first set of cases, and running experiments in a lab for the second set of cases. In an embodiment, the method may further comprise compiling experimental outputs from the experiments, and running physics based simulations for the second set of cases, where the physics based simulations use the reduced order physics simulation model. In an embodiment, the method may further comprise compiling model outputs from the simulations, and correlating the model outputs with the experimental outputs with a second machine learning algorithm to provide the hybrid machine learning model.

### BRIEF DESCRIPTION OF THE DRAWINGS

FIG. 1A is a process flow diagram depicting a process for creating a reduced order physics simulation model, in accordance with an embodiment.

FIG. 1B is a process flow diagram depicting a process for creating hybrid machine learning model, in accordance with an embodiment.

FIG. 1C is a process flow diagram depicting a process for deploying a hybrid machine learning model on new process and/or hardware conditions, in accordance with an embodiment.

FIG. 2 is a perspective view illustration of a radical oxidation tool, in accordance with an embodiment.

FIG. 3 is a diagram illustrating the use of a hybrid model in a radical oxidation tool, in accordance with an embodiment.

FIGS. 4A-4D are graphs depicting the predictions of the hybrid model compared to actual results, in accordance with various embodiments.

FIG. 5A is a control architecture that illustrates the use of a virtual sensor, in accordance with an embodiment.

FIG. 5B is a control architecture that incorporates a virtual sensor, in accordance with an embodiment.

FIG. 6 is a more detailed illustration of a control architecture that incorporates a virtual sensor and a loop for providing updates to the models generating the virtual sensor readings, in accordance with an embodiment.

FIG. 7A is a control architecture with a virtual sensor and a controller for updating parameters in the models for generating the virtual sensor readings, in accordance with an embodiment.

FIG. 7B is a control architecture with a virtual sensor and a controller that utilizes a Kalman filter, in accordance with an embodiment.

FIG. 8 illustrates a block diagram of an exemplary computer system, in accordance with an embodiment of the present disclosure.

### DETAILED DESCRIPTION

Methods of modelling processing conditions in a semiconductor processing tool and the use of virtual sensors are described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects are not described in detail in order to not unnecessarily obscure embodiments of the present disclosure. Furthermore, it is to be understood that the various embodiments shown in the Figures are illustrative representations and are not necessarily drawn to scale.

As noted above, there is no quantitative and objective approach to estimate performance of a new hardware setup or to provide new processing parameters after a hardware change. As such, complex and subjective process design techniques are currently used. This leads to an expensive process design, and may not identify the optimal processing parameters for a given hardware setup. Additionally, in a high volume manufacturing (HVM) environment, multiple tools may be used in parallel to execute a desired process on substrates. The processing parameters for each of the tools may need to be different. As such, each tool must undergo expensive process optimizations.

Accordingly, embodiments disclosed herein include a machine-learning model that uses features extracted from one or more physics-based models of the system. The method described herein includes extracting features from the physics based models and using experimental data from the processing of physical substrates to train a machine learning algorithm. Particularly, the methods disclosed herein may include generating a reduced order model (ROM) of the physics based simulations, and using the ROM in conjunction with experimental data in order to generate a hybrid machine learning model. The hybrid machine learning model may then be deployed in order to predict on-wafer results for new process conditions, new hardware, or even different processing tools.

The hybrid machine learning model may be generated for any semiconductor processing tool. For example, the hybrid machine learning model may be used for a deposition tool or an etching tool. In a particular embodiment, the hybrid machine learning model may be generated for a radical oxidation tool.

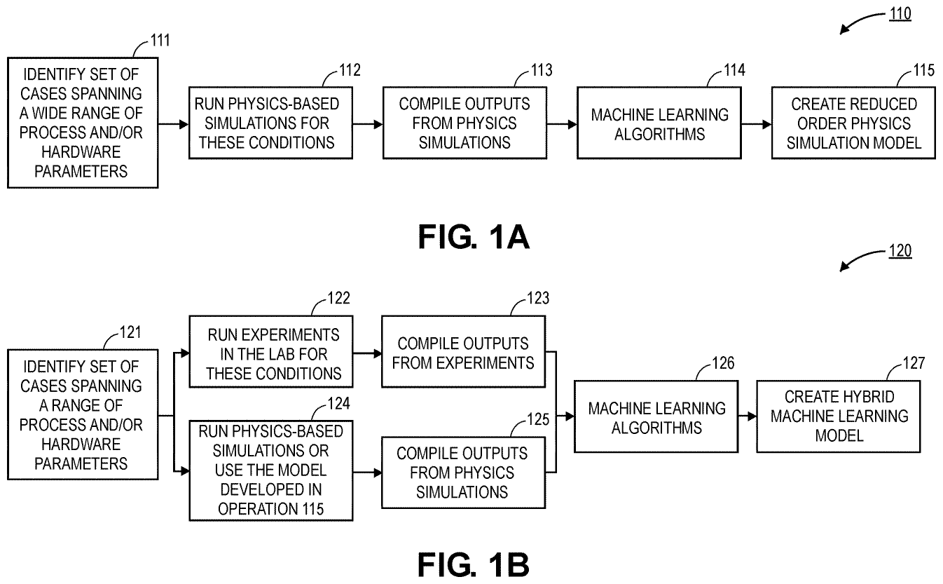

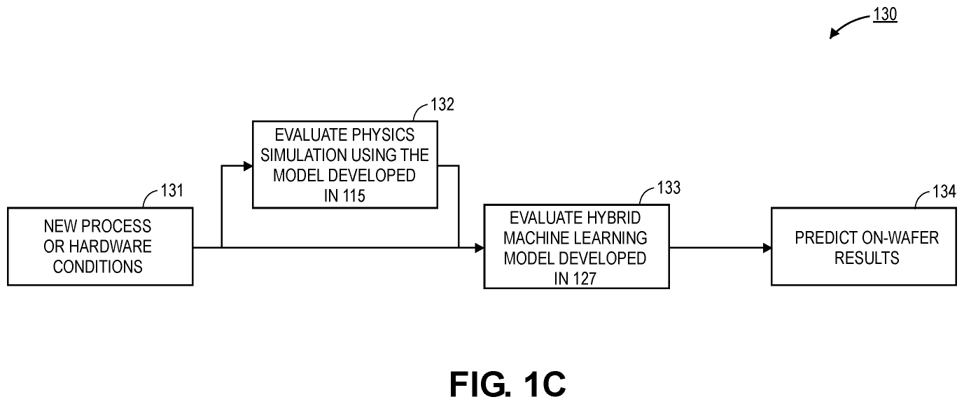

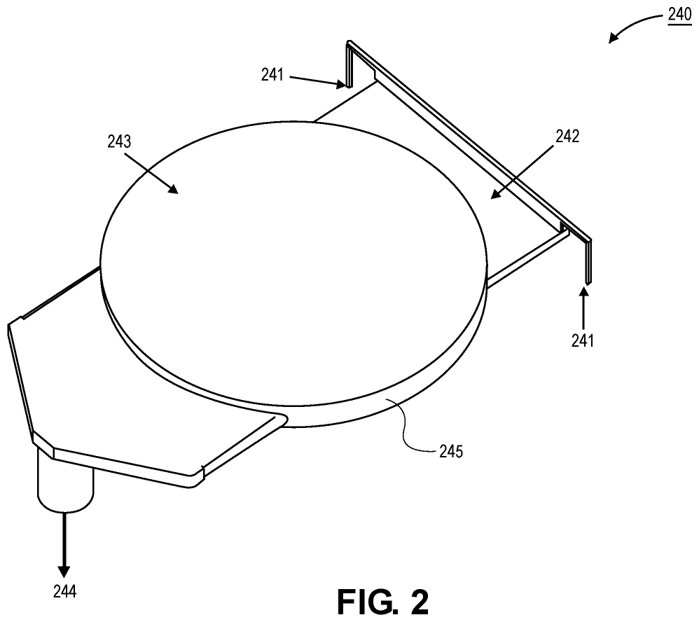

Referring now to FIG. 1A, a process flow diagram depicting a process 110 for forming a reduced order physics simulation model is shown, in accordance with an embodiment. In an embodiment, the process 110 begins with operation 111 which comprises identifying a set of cases spanning a wide range of process and/or hardware parameters. A wide range of process and/or hardware parameters is possible since the process and/or hardware parameters are being modeled computationally. The cost of computation is significantly lower than the cost that would be required to run physical experiments with the various process and/or hardware parameters.

In an embodiment, the process 110 continues with operation 112 which comprises running physics-based simulations for the set of cases. The physics-based simulations are calculated to determine the outputs based on how the process and/or hardware parameters interact with each other following the physical laws of nature. The physics-based simulations are run computationally. That is, no substrates need to be actually processed in order to determine the outcomes of the physics-based simulations.

In an embodiment, the process 110 continues with operation 113 which comprises compiling outputs from the physics-based simulations. The outputs may be referred to as simulation outputs since they are the result of a simulation instead of the processing of actual substrates.

In an embodiment, the process 110 continues with operation 114 which comprises applying the simulation outputs to a machine learning algorithm. The machine learning algorithm correlates the process and/or hardware parameters to the simulation outputs in order to generate a reduced order physics simulation model 115. The machine learning algorithm comprises a mathematical model that correlates the simulation outputs to the process and/or hardware parameters. The models may comprise one or more of single value decomposition (SVD), principal orthogonal decomposition (POD), Gaussian process regression, other kernel based regressions, response surface based regression, neural network models, regression using radial basis function, and regression models that account for spatial connectivity. In an embodiment, the machine learning model typically has model parameters that need to be determined. One of the main tasks involved in forming the reduced order model involves choosing the combination of the mathematical model and the model parameters that yield the best fit of the simulation outputs to the process and/or hardware parameters. The reduced order simulation model 115 allows for subsequent process and/or hardware parameters to be investigated in a shorter period of time than what is necessary when running the full physics-based simulations.

Referring now to FIG. 1B, a process 120 for creating a hybrid machine learning model is shown, in accordance with an embodiment. As will be described in greater detail below, the hybrid machine learning model allows for on-substrate results to be predicted computationally based on a given set of process and/or hardware parameters. The hybrid machine learning model may be applied to changes on a single tool or even on different instances of the tool.

In an embodiment, the process 120 may begin with operation 121 which comprises identifying a set of cases spanning a range of process and/or hardware parameters. The range of cases in operation 121 may be smaller than the range of cases in operation 111. This is because the range of cases will be investigated using physical substrates, and is therefore more time and cost intensive than running only the physics-based simulations.

In an embodiment, process 120 may continue with a pair of branches that may be executed in parallel (though they need not be executed in parallel in all embodiments). A first branch starts with operation 122 which comprises running experiments in the lab for the set of cases identified in operation 121. The experiments include physically processing substrates in accordance with the selected process and/or hardware parameters. In an embodiment, the first branch may continue with operation 123 which comprises compiling outputs from the experiments. The outputs from the experiments may include on substrate outputs, such as, for example, deposition thickness, etch rate, composition, uniformity, and the like.

In an embodiment, the second branch may begin with operation 124 which comprises running physics-based simulations for the set of the selected cases. In some embodiments, the physics-based simulation is the same simulation used in operation 112. In other embodiments, the physics-based simulation may utilize the reduced order physics simulation model developed in process 110. When the reduced order physics simulation model is used in operation 124 the time and computational resources necessary for running the simulations may be reduced. In an embodiment, the second branch may continue with compiling outputs from the physics-based simulations.

In an embodiment, the first branch and the second branch merge back together at operation 126 which comprises using a machine learning algorithm to correlate the compiled experimental outputs with the compiled physics-based simulation outputs. The machine learning algorithm comprises a mathematical model that correlates the compiled experimental outputs with the compiled physics-based simulation outputs. The models may comprise one or more of single value decomposition (SVD), principal orthogonal decomposition (POD), Gaussian process regression, other kernel based regressions, response surface based regression, neural network models, regression using radial basis function, and regression models that account for spatial connectivity. The machine learning algorithm determines the choice of the mathematical model and corresponding model parameters to minimize the error between the predicted on-substrate property and the experimentally measured on-substrate property. The machine learning algorithm outputs a hybrid machine learning model 127 that is able to take process and/or hardware parameters as inputs and output on substrate outputs such as, for example, deposition thickness, etch rate, composition, uniformity, and the like.

Referring now to FIG. 1C, a process 130 for deploying the hybrid machine learning model 127 is shown, in accordance with an embodiment. In an embodiment, the process 130 begins with selecting new process and/or hardware conditions. The new process and/or hardware conditions may be any process and/or hardware conditions, including those that are different or outside the range of the process and/or hardware conditions investigated in operations 111 and 121. In some embodiments, the process and/or hardware conditions may even be on a different instance of the tool than the tool investigated in process 120. That is, once the hybrid machine learning model is developed, it has the flexibility to be deployed throughout a fabrication facility on similar processing tools even when there is no experimental data available.

In an embodiment, process 130 may continue with operation 132, which comprises evaluating a physics simulation using the reduced order physics simulation model developed in operation 115 (provided the hardware parameters were included in the formation of the model developed in operation 115) or by running physics simulations. The output of the reduced order physics simulation or physics simulations may then be fed into the hybrid machine learning model at operation 133. The reduced order physics simulation model allows for the process and/or hardware conditions to be mapped into the physics space for use by the hybrid machine learning model at operation 133.

Operation 133 may comprise evaluating the hybrid machine learning model that was developed at operation 127 above. The hybrid machine learning model is capable of outputting on-substrate results at 134. That is, new process and/or hardware conditions may be mapped directly to on-substrate results such as, for example, deposition thickness, etch rate, composition, uniformity, and the like. This is a significant improvement over existing processes that require physical testing of substrates in order to obtain on-substrate results.

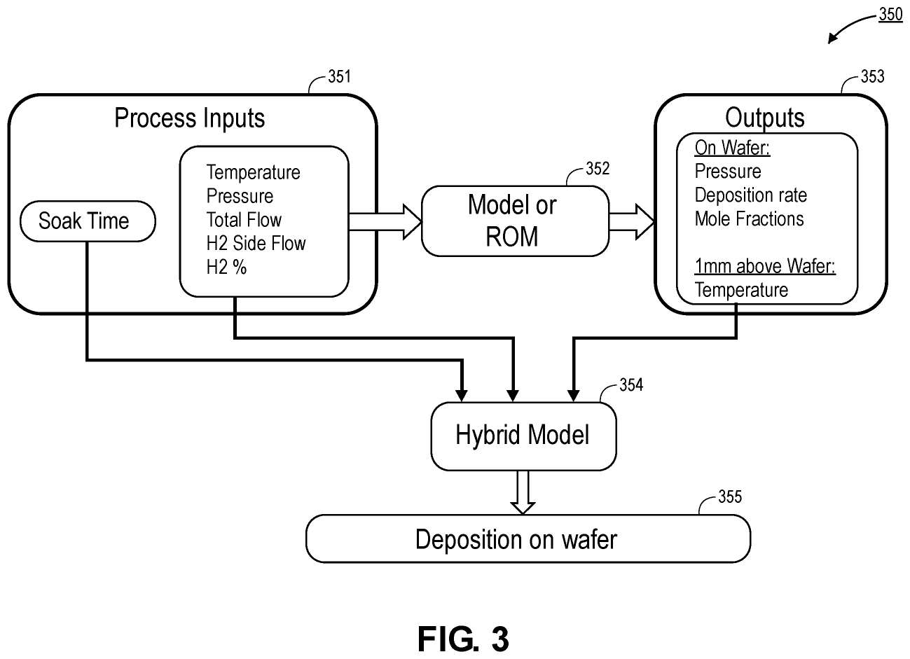

Referring now to FIG. 2, a perspective view illustration of a semiconductor processing tool 240 is shown, in accordance with an embodiment. While a particular semiconductor processing tool 240 is shown, it is to be appreciated that the semiconductor processing tool 240 may be any processing tool typical of semiconductor fabrication, such as a deposition tool, an etching tool, or the like. In the particular embodiment shown in FIG. 2, the semiconductor processing tool is a radical oxidation tool.

In an embodiment, the semiconductor processing tool 240 may comprise gas inlets 241. Gasses may be flown into the gas inlets 241 and proceed through a tunnel 242 into a chamber 245. The top of the chamber 245 may be sealed with a quartz plate 243. Heating elements (not shown) may be disposed over the quartz plate 243 to provide rapid thermal control within the chamber 245. In an embodiment, byproducts and excess reactants may be removed from the chamber 245 by an outlet 244. The outlet 244 may be fluidically coupled to a vacuum pump (not shown) or the like.

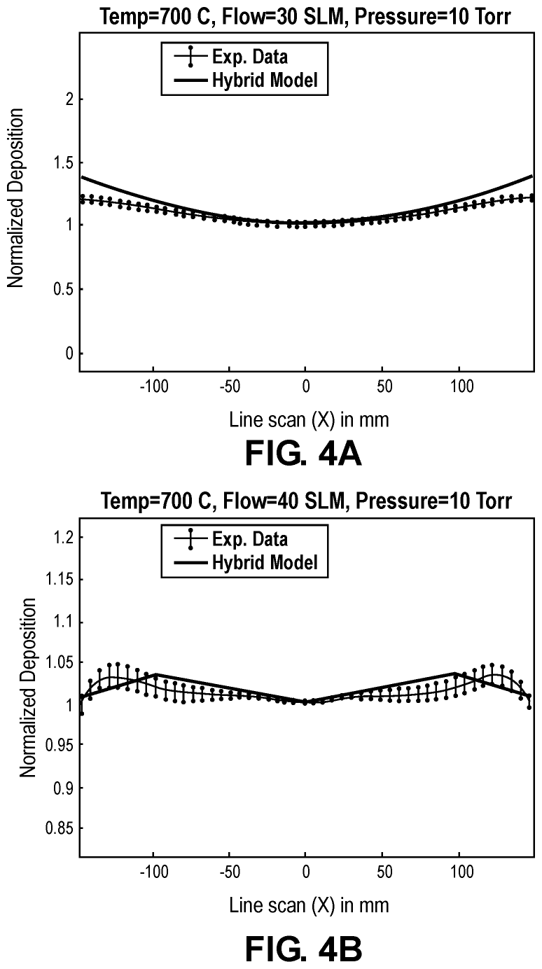

Referring now to FIG. 3, a diagram 350 showing how the hybrid model may be used with a radical oxidation tool is shown as an example. As shown, a set of process inputs are provided in block 351. The process inputs may include processing parameters used in a radical oxidation process, such as, but not limited to soak time, temperature, pressure, total gas flow, H₂ side flow, and H₂%. In an embodiment, the process inputs may also include hardware configurations, such as, but not limited to the geometry of various portions of the tool (e.g., injection cartridge), a spacing between a substrate and the quartz plate 343, and the like.

In an embodiment, the process inputs of block 351 are provided to the physics-based model or a reduced order physics-based model at block 352. The model may provide outputs based on physics equations. For example, on wafer outputs may include pressure, deposition rate, and mole fractions, and off the wafer outputs may include temperature.

In an embodiment, the process inputs of block 351 and the model outputs of block 353 may be fed into a hybrid model 354. The hybrid model 354 may be substantially similar to any of the hybrid models described in greater detail above. The hybrid model processes the incoming data from the process inputs of block 351 and the model outputs of block 353, and provides an output of the expected deposition on the wafer at block 355.

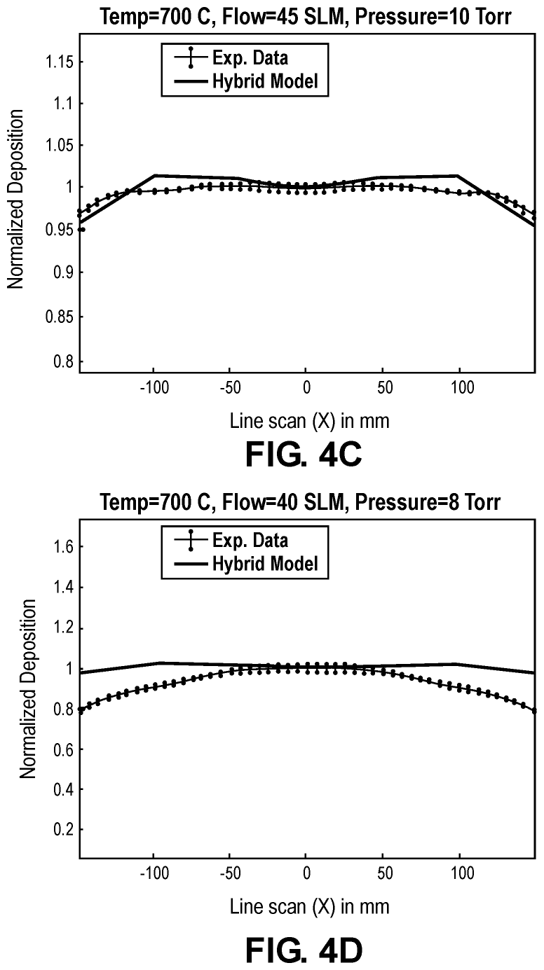

It has been shown that the hybrid model provides an accurate mapping of the expected outputs on the substrate. For example, FIGS. 4A-4D are plots of the normalized deposition across a substrate for various processing parameters. In FIGS. 4A-4D, a hybrid model of a radical oxidation process was generated using processes similar to those described above, and deployed on a tool that had a significant change in the geometry of the injection cartridge. The hybrid model was used to make a prediction of the deposition across the surface of the substrate, and experimental data was subsequently obtained to confirm the accuracy of the hybrid model. In FIGS. 4A-4D, the hybrid model predictions matched the experimental data well. For example, less than 9% mean error was obtained across the various processing conditions.

In yet another embodiment disclosed herein, physics-based models and machine learning can be harnessed to provide virtual sensors within a semiconductor processing tool. This is particularly beneficial for determining processing conditions that cannot be easily measured (or measured at all) using traditional physical sensors. Placing physical sensors within a processing tool is expensive and intrusive. However, process control is effective when the processing conditions (especially on the substrate) are known. Physics-based models can address this issue by providing virtual sensors that give details of on-substrate properties without having to use physical sensors. The physics-based models may also be used to aid in testing the controller and performing virtual experiments for controller development.

Virtual sensors may be used to aid in the control of the processing operation. Like physical sensors, virtual sensor outputs may be compared against set-point values by a controller in order to determine if changes need to be made to the processing operation. Furthermore, embodiments disclosed herein may utilize machine learning or artificial intelligence in order to continuously update the physics-based models in order to improve the accuracy of the virtual sensor outputs.

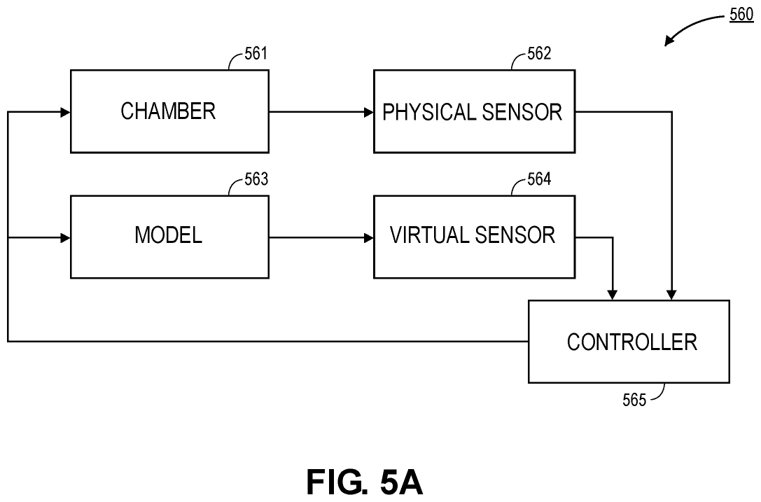

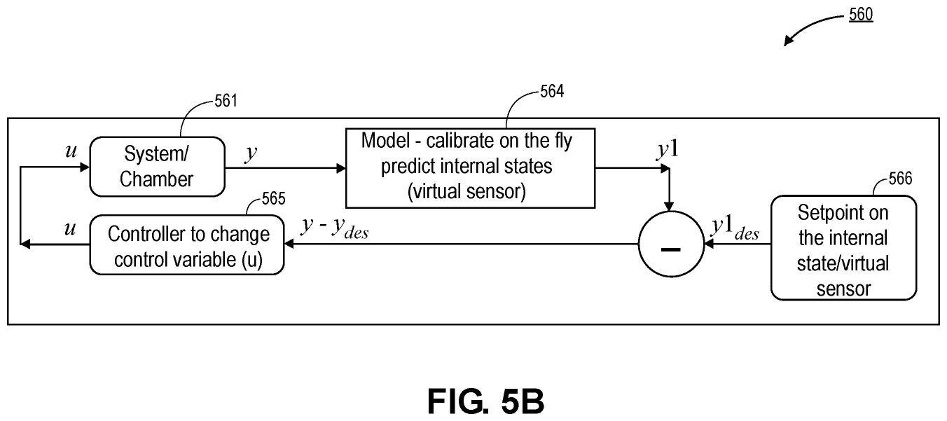

Referring now to FIG. 5A a simplified diagram of the control architecture 560 for a processing tool is shown, in accordance with an embodiment. As shown, the chamber 561 may include a physical sensor 562 that feeds into the controller 565. The controller sends back a control signal to the chamber 561 in order to adjust one or more processing conditions. In another loop, a model 563 (e.g., a physics-based model) is connected to a virtual sensor 564. The virtual sensor 564 outputs values to the controller 565. A more detailed description of the virtual sensor 564 is provided below.

Referring now to FIG. 5B, a more detailed illustration of the control architecture 560 is shown, in accordance with an embodiment. In an embodiment, an output variable (or vector) y is fed into the virtual sensor 564. The virtual sensor outputs a virtual sensor variable (or vector) y1. A setpoint 566 of the desired virtual sensor variable y1_{des} is compared against the output variable y by the controller 565. Depending on the calculated difference, a control signal u is provided to the chamber 561 to change the output variable y.

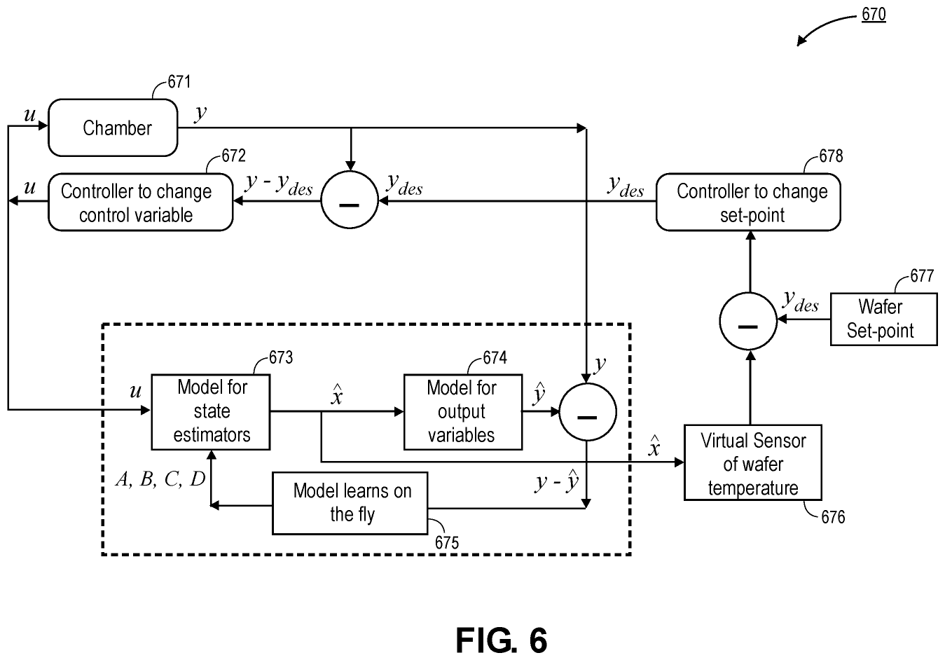

Referring now to FIG. 6, a diagram of the control architecture 670 of a tool that includes a virtual sensor 676 that is coupled to an updateable model 673 is shown, in accordance with an embodiment. In an embodiment, the control architecture 670 begins with chamber 671. Chamber 671 may refer to any portion of a semiconductor processing tool. In an embodiment, an output variable y (or vector) is compared with a desired output variable y_{des} by a first controller 672. The first controller 672 provides an input variable u (or vector) back to the chamber 671. The input variable u is also fed to the model 673, which will be described in detail below. The desired output variable y_{des} is generated by a second controller 678 that utilizes the virtual sensor data.

In an embodiment, the model 673 is a physics-based model. That is, the model 673 calculates the reactions within the chamber 671 from a physics-based perspective in order to provide an estimate of system state variables \hat{x} (or vectors). The estimated system state variable \hat{x} can be a virtual sensor value. That is, the measured value of \hat{x} can be a desired but typically not known or measured value. For example, the estimated state variable \hat{x} can be a wafer temperature in some embodiments. However, it is to be appreciated that other estimated state variables \hat{x} or even multiple different estimated state variables \hat{x} can be provided by the model 673.

In an embodiment, the estimated state variable \hat{x} is fed to the virtual sensor 676 where it can be accessed by the system. In a particular embodiment, the virtual sensor 676 feeds the estimated state variable \hat{x} to a second controller 678 that compares the estimated state variable \hat{x} to a setpoint state variable x_{des}. Depending on the difference between \hat{x} and x_{des}, the controller delivers a y_{des} to the first controller.

In an embodiment, the model 673 may be continuously updated through a machine learning or artificial intelligence block 675. Particularly, the estimated state variable \hat{x} is also fed to a second model 674. The second model outputs an estimated output variable ŷ (or vector). The estimated output variable ŷ is compared to the output variable y from the chamber 671. The machine learning block 675 can then alter the first model 673 (e.g., using state space matrices A, B, C, and/or D) to refine the first model in order to bring the estimated output variable ŷ closer to the output variable y. This also leads to a more accurate prediction of the estimated state variable \hat{x}.

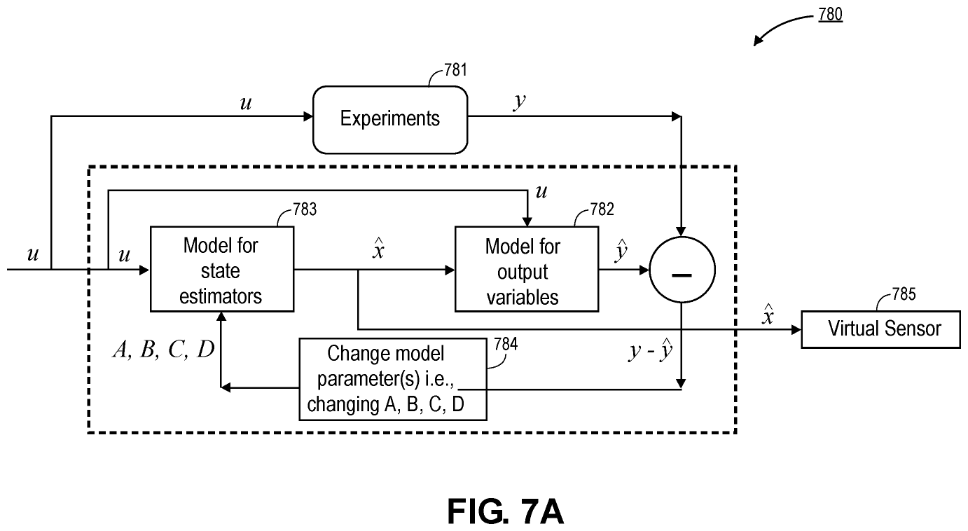

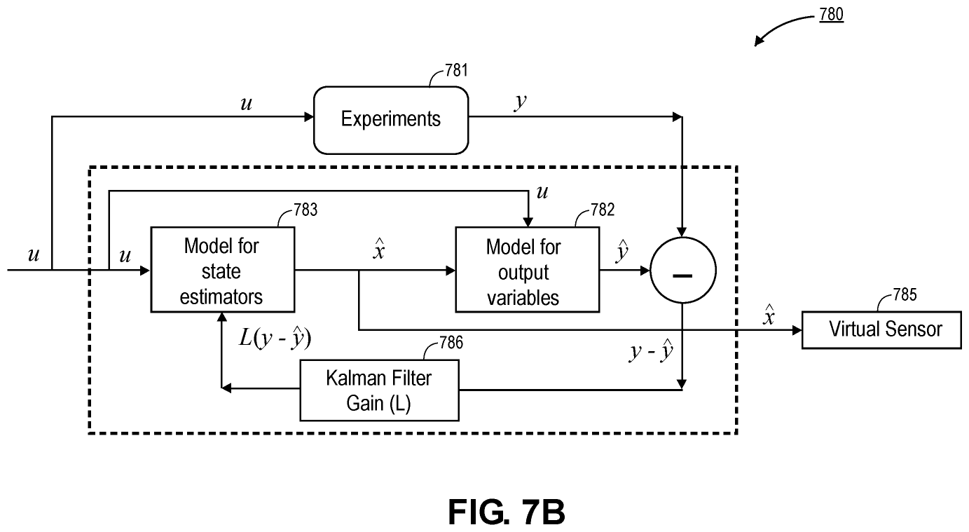

Referring now to FIG. 7A, a diagram of a control architecture 780 with a virtual sensor 785 is shown, in accordance with an embodiment. During the course of experiments 781 in a chamber, output variables y are provided to a controller 784. The controller compares the output variables y to estimated output variables ŷ generated through the use of various physics models 783 and 782. In an embodiment, the model for the state estimator 783 is controlled by Equation 1, and the model for the output variables 782 is controlled by Equation 2.

\hat{x}=A \hat{x}(t)+Bu(t)+L[y(t)−ŷ(t)] Equation 1

ŷ=C\hat{x}(t)+Du(t) Equation 2

In Equations 1 and 2, the matrices A, B, C, and D are functions of the parameters of the experiment 781 and can be obtained using physics-based models or a system model. When a statistical model is used, matrices A, B, C, and D may not have a physical basis, and changing A, B, C, or D will not correlate to physical parameters. Additionally, it is to be appreciated that A, B, C, and D may also be functions of time as wells as x and y.

In an embodiment, the assumption of the control architecture 780 is that the error between the measured output y and the predicted output ŷ is because of uncertain parameters in the system and that the physics are correct. That is, the model for state estimators 783 is not changed for physics. The noise in the system is not taken into account. In other words, the noise in the system is offset by changes of parameter values A, B, C, or D. Changing model parameters may be done by optimization and/or inverse methods so long as the controller 784 has a good hypothesis to start with. Furthermore, it is to be appreciated that the computational effort depends on the matrices A, B, C, and D. With today's computing capabilities the computational effort is well within the realm of being done in real time. As such, an in real time virtual sensor 785 is possible.

Referring now to FIG. 7B, a diagram of a control architecture 780 with a virtual sensor 785 is shown, in accordance with an embodiment. During the course of experiments 781 in a chamber, output variables y are provided to a controller 786. The controller 786 compares the output variables y to estimated output variables 9 generated through the use of various physics models 783 and 782. In an embodiment, the model for the state estimator 783 is controlled by Equation 1, and the model for the output variables 782 is controlled by Equation 2. In contrast to the embodiment in FIG. 7A, the controller 786 may apply a Kalman filter with a gain L.

In Equations 1 and 2, the matrices A, B, C, and D are functions of the parameters of the experiment 781 and can be obtained using physics-based models, a system model, or a statistical model. Additionally, it is to be appreciated that A, B, C, and D may also be functions of time as wells as x and y.

In an embodiment, the assumption of the control architecture 780 is that the error between the measured output y and the predicted output ŷ is is because of error sources and that physics and parameters are correct. That is, the model for 783 for state estimators is not changed for physics but is corrected to account for the errors. The noise in the system is also taken into account. This model framework can be used for predicting state estimators and allows for an in real time virtual sensor 785. Additionally, the model will correct itself automatically for any error between measured and predicted outputs by changing the parameters of the models 783 and/or 782.

In an embodiment, the controller architectures with virtual sensor functionality described herein can be tested in different ways. In one embodiment, the controller architectures may be tested on functional chambers or systems. That is, physical substrate processing may be used to test the controller architectures. This process requires tool time and other resources in order to implement. In another embodiment, the controller architectures with virtual sensor functionality may be tested through software simulations. For example, a virtual chamber modeled with physics-based models and/or hybrid models can be used to test the controller architecture. Such an embodiment only requires computational resources and saves on valuable tool time, substrates, and other physical resources.

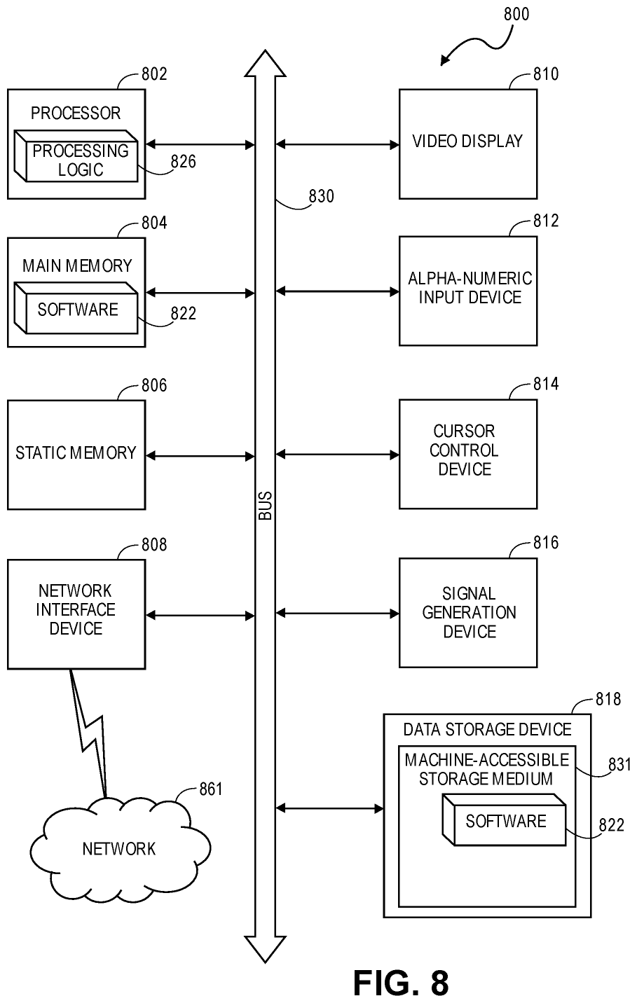

FIG. 8 illustrates a diagrammatic representation of a machine in the exemplary form of a computer system 800 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 800 includes a processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), MRAM, etc.), and a secondary memory 818 (e.g., a data storage device), which communicate with each other via a bus 830.

Processor 802 represents one or more general-purpose processing devices such as a microprocessor, central processing unit, or the like. More particularly, the processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. Processor 802 is configured to execute the processing logic 826 for performing the operations described herein.

The computer system 800 may further include a network interface device 808. The computer system 800 also may include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium (or more specifically a computer-readable storage medium) 832 on which is stored one or more sets of instructions (e.g., software 822) embodying any one or more of the methodologies or functions described herein. The software 822 may also reside, completely or at least partially, within the main memory 804 and/or within the processor 802 during execution thereof by the computer system 800, the main memory 804 and the processor 802 also constituting machine-readable storage media. The software 822 may further be transmitted or received over a network 820 via the network interface device 808.

While the machine-accessible storage medium 832 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of creating a hybrid machine learning model.

Thus, methods for generating a hybrid machine learning model have been disclosed.

What is claimed is:

1. A method of creating a hybrid machine learning model, comprising:
identifying a first set of cases spanning a first range of process and/or hardware parameters;
running experiments in a lab for the first set of cases;
compiling experimental outputs from the experiments;
running physics based simulations for the first set of cases;
compiling model outputs from the simulations; and
correlating the model outputs with the experimental outputs with a machine learning algorithm to provide the hybrid machine learning model.

2. The method of claim 1, wherein the physics based simulation is a reduced order physics simulation model.

3. The method of claim 2, wherein the reduced order physics simulation model is generated by a method comprising:
identifying a second set of cases spanning a second range of process and/or hardware parameters;
running a physics based simulation for the second set of cases;
compiling outputs from the physics based simulation; and
using a second machine learning algorithm to generate the reduced order physics simulation model.

4. The method of claim 3, wherein the second set of cases is larger than the first set of cases.

5. The method of claim 3, wherein the outputs from the physics based simulation comprise one or more of species concentrations, fluxes, and energies on wafer and/or additional quantities such as pressure, flow (velocity) and temperature at locations away from the wafer.

6. The method of claim 3, further comprising:
selecting a new hardware and/or process condition;
evaluating the new hardware and/or process condition with the reduced order physics simulation model;
evaluating the new hardware and/or process condition with the hybrid machine learning model; and
predicting on-wafer results based on the evaluation of the reduced order physics simulation model and the hybrid machine learning model.

7. The method of claim 6, wherein the new hardware and/or process condition is on a tool different than the tool used to generate the hybrid machine learning model.

8. The method of claim 1, wherein the model outputs comprise one or more of species concentrations, fluxes, and energies on wafer.

9. The method of claim 1, wherein the experimental outputs comprise a deposition rate or an etch rate.

10. The method of claim 1, wherein the hybrid machine learning model is for a radical oxidation tool.

11. A semiconductor processing tool comprising:
a chamber;
a controller for changing a control variable of the semiconductor processing tool, wherein the controller receives, as an input, a difference between a measured output variable from the chamber and an output variable set-point; and
a virtual sensor for generating an estimated system state variable that is used to determine the output variable set-point.

12. The semiconductor processing tool of claim 11, further comprising:
a second controller for changing the output variable setpoint, wherein the second controller receives, as an input, a difference between the estimated system state variable and a system state variable set-point.

13. The semiconductor processing tool of claim 12, further comprising:
a first model, wherein the first model receives the control variable as an input and outputs the estimated system state variable that is provided to the virtual sensor.

14. The semiconductor processing tool of claim 13, further comprising:
a second model, wherein the second model receives the estimated system state variable as an input and outputs an estimate of the output variable.

15. The semiconductor processing tool of claim 14, further comprising:
a machine learning algorithm, wherein the machine learning algorithm receives as an input a difference between the output variable and the estimate of the output variable, and wherein the machine learning algorithm updates the first model.

16. The semiconductor processing tool of claim 15, wherein the machine learning algorithm utilizes a Kalman filter.

17. The semiconductor processing tool of claim 12, wherein the estimated system state variable is a wafer temperature.

18. The semiconductor processing tool of claim 17, wherein the semiconductor processing tool is a radical oxidation tool.

19. A method of creating a hybrid machine learning model, comprising:
identifying a first set of cases spanning a first range of process and/or hardware parameters;
running a physics based simulation for the first set of cases;
compiling outputs from the physics based simulation;
using a first machine learning algorithm to generate a reduced order physics simulation model;
identifying a second set of cases spanning a second range of process and/or hardware parameters, wherein the second set of cases is smaller than the first set of cases;
running experiments in a lab for the second set of cases;
compiling experimental outputs from the experiments;
running physics based simulations for the second set of cases, wherein the physics based simulations use the reduced order physics simulation model;
compiling model outputs from the simulations; and
correlating the model outputs with the experimental outputs with a second machine learning algorithm to provide the hybrid machine learning model.

20. The method of claim 19, further comprising:
selecting a new hardware and/or process condition;
evaluating the new hardware and/or process condition with the reduced order physics simulation model;
evaluating the new hardware and/or process condition with the hybrid machine learning model; and
predicting on-wafer results based on the evaluation of the reduced order physics simulation model and the hybrid machine learning model.
